(19) United States
(12) Patent Application Publication
(10) Pub. No.: US 2014/0048844 A1
(43) Pub. Date: Feb. 20, 2014

(54) TRENCH GATE TYPE POWER SEMICONDUCTOR DEVICE

(71) Applicant: SAMSUNG ELECTRO-MECHANICS CO., LTD., Gyunggi-do (KR)

(72) Inventors: In Hyuk Song, Gyunggi-do (KR); Jae Hoon Park, Gyunggi-do (KR); Dong Soo Seo, Gyunggi-do (KR)

(73) Assignee: SAMSUNG ELECTRO-MECHANICS CO., LTD., Gyunggi-do (KR)

(21) Appl. No.: 13/692,449

(22) Filed: Dec. 3, 2012

(30) Foreign Application Priority Data
Aug. 14, 2012 (KR) 10-2012-0088904

(51) Int. Cl. H01L 29/78

(52) U.S. Cl. CPC H01L 29/7827
USPC 257/139; 257/330

(57) ABSTRACT

Disclosed herein is a trench gate type power semiconductor device including: a semiconductor substrate; a drift layer formed on the semiconductor substrate; a well layer formed on the drift layer; trenches formed to arrive at the drift layer while penetrating through the well layer in a thickness direction; first insulating films formed from bottom surfaces of the trenches up to a predetermined height; first electrodes formed at a height lower than that of the first insulating films in the trenches; interlayer dielectrics formed up to the same height as that of the first insulating films in the trenches; and a second electrode formed on the well layer, a portion of the first surface corresponding to the trenches being protruded into the trenches to contact the interlayer dielectrics.

### CROSS REFERENCE TO RELATED APPLICATION

This application claims the benefit of Korean Patent Application No. 10-2012-0088904, filed on Aug. 14, 2012, entitled “Trench Gate Type Power Semiconductor Device”, which is hereby incorporated by reference in its entirety into this application.

### BACKGROUND OF THE INVENTION

1. Technical Field

The present invention relates to a trench gate type power semiconductor device.

2. Description of the Related Art

Since an insulated gate bipolar transistor (IGBT) has high input impedance of a field effect transistor and a high current drive capability of a bipolar transistor, it has been mainly used as a power switching device.

As the insulated gate bipolar transistor, a plane gate type insulated gate bipolar transistor and a trench gate type insulated gate bipolar transistor are mainly used. Recently, the trench gate type insulated gate bipolar transistor capable of having an increased current density and a decreased size has been mainly developed and researched.

Meanwhile, an insulated gate bipolar transistor (IGBT) according to the prior art has been disclosed in US Patent Laid-Open Publication No. 2011-180813.

### SUMMARY OF THE INVENTION

The present invention has been made in an effort to provide a trench gate type power semiconductor device having a fine pitch trench simultaneously with preventing misalignment from being generated at the time of forming a contact surface between an emitter electrode and a substrate.

Further, the present invention has been made in an effort to provide a trench gate type power semiconductor device capable of solving a contact resistance increase problem by increasing a contact area between an emitter electrode and a substrate.

Further, the present invention has been made in an effort to provide a trench gate type power semiconductor device capable of preventing a wire from being opened by removing a step of a surface of an emitter electrode to increase a wire bonding area at the time of assembling a package.

According to a preferred embodiment of the present invention, there is provided a trench gate type power semiconductor device including: a first conductive type semiconductor substrate having one surface and the other surface; a second conductive type drift layer formed on one surface of the semiconductor substrate; a first conductive type well layer formed on the drift layer; trenches formed from a surface of the well layer so as to arrive at the drift layer while penetrating through the well layer in a thickness direction; first insulating films formed on inner walls of the trenches and formed from bottom surfaces of the trenches up to a predetermined height; first electrodes formed at a height lower than that of the first insulating films in the trenches; interlayer dielectrics formed on the first electrodes in the trenches and formed up to the same height as that of the first insulating films; and a second electrode formed on the well layer and having a first surface contacting the surface of the well layer and a second surface facing the first surface, a portion of the first surface corresponding to the trenches being protruded into the trenches to contact the interlayer dielectrics.

The first conductive type may be a P type and the conductive type may be an N type.

The trench gate type power semiconductor device may further include: N type second electrode regions formed in the well layer so as to contact the first surface of the second electrode and outer walls of each of the trenches, formed between the trenches adjacent to each other so as to be spaced apart from each other, and having a concentration higher than that of the drift layer; and P type body regions formed between the second electrode regions spaced apart from each other in the well layer so as to contact the second electrode regions and the first surface of the second electrode and having a concentration higher than that of the well layer, wherein the number of trenches is plural.

The trench gate type power semiconductor device may further include: N type second electrode regions formed between the trenches adjacent to each other in the well layer so as to contact the first surface of the second electrode and outer walls of each of the trenches, formed to be spaced apart from each other in a length direction of the trench, and having a concentration higher than that of the drift layer; and P type body regions formed between the second electrode regions spaced apart from each other so as to contact the second electrode regions and the first surface of the second electrode and having a concentration higher than that of the well layer, wherein the number of trenches is plural.

The trench gate type power semiconductor device may further include an N type buffer layer formed between the P type semiconductor substrate and the N type drift layer and having a concentration higher than that of the drift layer.

The trench gate type power semiconductor device may further include an N type layer formed between the N type drift layer and the P type well layer and having a concentration higher than that of the drift layer.

The first electrode may be made of poly silicon.

The first electrode may be a gate electrode and the second electrode may be an emitter electrode.

The interlayer dielectric may be made of boron phosphorus silicate glass (BPSG).

The trench gate type power semiconductor device may further include a third electrode formed on the other surface of the semiconductor substrate.

The third electrode may be a collector electrode.

According to another preferred embodiment of the present invention, there is provided a trench gate type power semiconductor device including: a first conductive type semiconductor substrate having one surface and the other surface; a second conductive type drift layer formed on one surface of the semiconductor substrate; a first conductive type well layer formed on the drift layer; trenches formed from a surface of the well layer so as to arrive at the drift layer while penetrating through the well layer in a thickness direction; first insulating films formed on inner walls of the trenches and formed from bottom surfaces of the trenches up to a predetermined height; first electrodes formed at a height lower than that of the first insulating films in the trenches; interlayer dielectrics formed on the first electrodes in the trenches and formed up to the same height as that of the first insulating films; a second electrode formed on the well layer and having a first surface contacting the surface of the well layer and a second surface facing the first surface, a portion of the first surface corresponding to the trenches being protruded into the trenches to contact the interlayer dielectrics; N type second electrode regions formed in the well layer so as to contact the first surface of the second electrode and outer walls of each of the trenches, formed between the trenches adjacent to each other so as to be spaced apart from each other, and having a concentration higher than that of the drift layer; and P type body regions formed between the second electrode regions spaced apart from each other in the well layer so as to contact the second electrode regions and the first surface of the second electrode and having a concentration higher than that of the well layer, wherein the first conductive type is a P type, the conductive type is an N type, and the number of trenches is plural.

According to still another preferred embodiment of the present invention, there is provided a trench gate type power semiconductor device including: a first conductive type semiconductor substrate having one surface and the other surface; a second conductive type drift layer formed on one surface of the semiconductor substrate; a first conductive type well layer formed on the drift layer; trenches formed from a surface of the well layer so as to arrive at the drift layer while penetrating through the well layer in a thickness direction; first insulating films formed on inner walls of the trenches and formed from bottom surfaces of the trenches up to a predetermined height; first electrodes formed at a height lower than that of the first insulating films in the trenches; interlayer dielectrics formed on the first electrodes in the trenches and formed up to the same height as that of the first insulating films; a second electrode formed on the well layer and having a first surface contacting the surface of the well layer and a second surface facing the first surface, a portion of the first surface corresponding to the trenches being protruded into the trenches to contact the interlayer dielectrics; N type second electrode regions formed between the trenches adjacent to each other in the well layer so as to contact the first surface of the second electrode and outer walls of each of the trenches, formed to be spaced apart from each other in a length direction of the trench, and having a concentration higher than that of the drift layer; and P type body regions formed between the second electrode regions spaced apart from each other so as to contact the second electrode regions and the first surface of the second electrode and having a concentration higher than that of the well layer, wherein the first conductive type is a P type, the conductive type is an N type, and the number of trenches is plural.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view showing a structure of a trench gate type power semiconductor device according to a first preferred embodiment of the present invention;

FIG. 2 is a cross-sectional view of the trench gate type power semiconductor device according to the first preferred embodiment of the present invention taken along the line A-A′ of FIG. 1;

FIG. 3 is a perspective view showing a structure of a trench gate type power semiconductor device according to a second preferred embodiment of the present invention; and

FIG. 4 is a cross-sectional view of the trench gate type power semiconductor device according to the second preferred embodiment of the present invention taken along the line B-B′ of FIG. 3.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Meanwhile, although an insulated gate bipolar transistor (IGBT) will be described by way of example in the present invention, the present invention is not particularly limited to the insulated gate bipolar transistor (IGBT), but may also be applied to a metal oxide semiconductor field effect transistor (MOSFET).

### First Preferred Embodiment

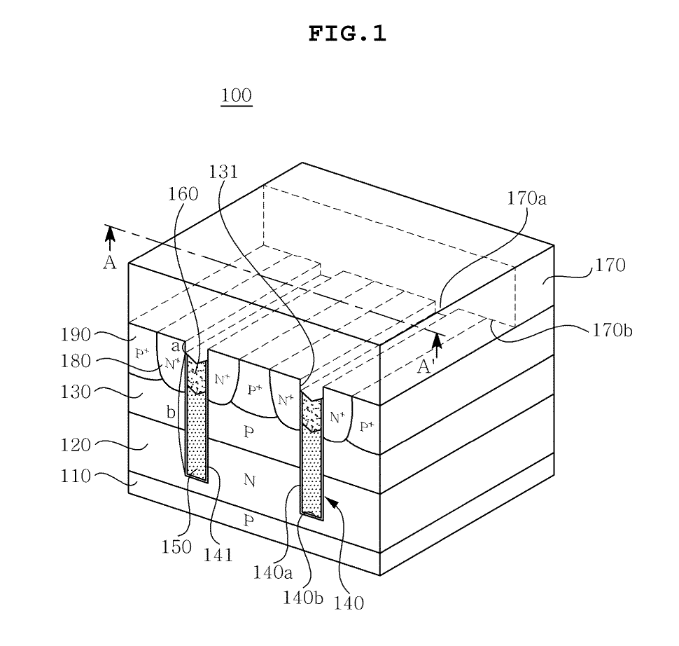

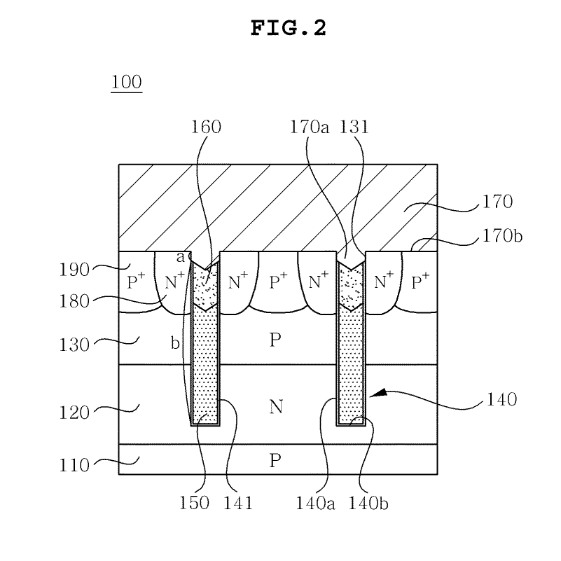

FIG. 1 is a perspective view showing a structure of a trench gate type power semiconductor device according to a first preferred embodiment of the present invention; and FIG. 2 is a cross-sectional view of the trench gate type power semiconductor device according to the first preferred embodiment of the present invention taken along the line A-A′ of FIG. 1.

Referring to FIG. 1 the trench gate type power semiconductor device 100 according to the first preferred embodiment of the present invention is configured to include a first conductive type semiconductor substrate 110, a second conductive type drift layer 120, a first conductive type well layer 130, trenches 140, first insulating films 141 formed on inner walls of the trenches 140, first electrodes 150 formed in the trenches 140, interlayer dielectrics 160 formed on the first electrodes 150 in the trenches 140, and a second electrode 170 formed on the well layer 130.

In the present embodiment, the first conductive semiconductor substrate 110 is formed of a silicon wafer, and the first conductive type may be a P type, but is not particularly limited thereto.

In addition, the semiconductor substrate 110 according to the present embodiment may have one surface and the other surface and include the second conductive type drift layer 120 formed on one surface thereof as shown in FIGS. 1 and 2 and a third electrode (not shown) formed on the other surface thereof. Here, the third electrode may be a collector electrode (not shown), and the semiconductor substrate 110 may serve as a collector region.

In the present embodiment, the second conductive type drift layer 120 may be formed on one surface of the semiconductor substrate 110 by an epitaxial growth method, but is not particularly limited thereto, and the second conductive type may be an N type, but is not particularly limited thereto.

In addition, although not shown in FIGS. 1 and 2, the trench gate type power semiconductor device 100 according to the first preferred embodiment of the present invention may include an N+ type buffer layer (not shown) formed between the P type semiconductor substrate 110 and the N type drift layer 120 and having a concentration higher than that of the drift layer 120. Here, the buffer layer (not shown) may also be formed by the epitaxial growth method, but is not particularly limited thereto.

The buffer layer (not shown), which is to allow a reverse voltage to be applied between the drift layer 120 and the well layer 130 in a forward blocking mode in which a gate electrode and an emitter electrode are short-circuited and a collector electrode is applied with a positive voltage with respect to the emitter electrode in an insulated gate bipolar transistor (IGBT), thereby preventing a depletion layer formed from a bonded surface between the drift layer 120 and the well layer 130 from being diffused to the P type semiconductor substrate 110, is formed, such that a thickness of the drift layer 120 may be decreased. Therefore, turn-on state losses of the device may be decreased.

In addition, at the time of forward conduction (in the case in which a predetermined voltage or more is applied to a gate to form a channel), as a concentration of the buffer layer (not shown) becomes high and a thickness thereof becomes thick, injection of holes from the P type semiconductor substrate 110 to the N type drift layer 120 is suppressed, thereby making it possible to increase a switching speed.

In the present embodiment, the first conductive type well layer 130 may be formed on the drift layer 120, as shown in FIGS. 1 and 2.

Here, the first conductive layer may be the P type, as described above, but is not particularly limited thereto.

Here, the P type well layer 130 may be formed by injecting P type impurities into a surface of the drift layer 120 and diffusing the P type impurities in a depth direction, but is not particularly limited thereto.

In the present embodiment, the trench 140 may be formed to arrive at the drift layer 120 while penetrating through the well layer 130.

More specifically, referring to FIGS. 1 and 2, the trench 140 may be formed from a surface 130a of the well layer 130 at a depth at which it arrive at the drift layer 120 while penetrating through the well layer 130 in a thickness direction. In this case, a plurality of trenches 140 having the same depth and the same width may be formed at a predetermined interval, but is not limited thereto.

Here, the term ‘same’ does not means accurately the same thickness in a mathematical meaning, but means substantially the same thickness in consideration of a design error, a manufacturing error, a measuring error, or the like. Hereinafter, a term ‘same’ used in the present description means “substantially the same”, as described above.

Here, the trench 140 may be formed by an etching process using a mask, but is not particularly limited thereto.

Further, in the present embodiment, a bottom surface 140b of the trench 140 may be positioned at the drift layer 120 as shown in FIGS. 1 and 2, but is not particularly limited thereto.

In the present embodiment, the trench 140 may have the first insulating film 141 formed on the inner wall thereof.

Here, the first insulating film 141 may be formed from the bottom surface 140b of the trench 140 up to a predetermined height (a region b) and may not be formed from an inlet portion of the trench 140 up to a predetermined depth (a region a).

This is to increase a contact area between a second electrode region 180, which is an emitter region, and a second electrode 170, which is an emitter electrode, to prevent an increase in contact resistance.

Here, the first insulating film 141 may be an oxide film formed by a thermal oxidizing process, but is not particularly limited thereto.

In the present embodiment, the first electrode 150 may be formed to contact the first insulating film 141 in the trench 140 and be formed up to a height lower than a height at which the first insulating film 141 is formed, but is not particularly limited thereto.

Here, the first electrode 150 may be made of poly silicon, but is not particularly limited thereto.

Further, in the present embodiment, the interlayer dielectric 160 for insulating between the first and second electrodes 150 and 170 may also be formed on the first electrode 150 in the trench 140 and be formed up to the same height as the height at which the first insulating film 141 is formed, but is not particularly limited thereto.

Here, the interlayer dielectric 160 may be made of boron phosphorus silicate glass (BPSG), but is not particularly limited thereto.

That is, as shown in FIGS. 1 and 2, in the present embodiment, both of the first electrode 150 and the interlayer dielectric 160 are formed in a form in which they are buried in the trench 140 and are formed so that a total thickness in which a thickness of the first electrode 150 and a thickness of the interlayer dielectric 160 formed on the first electrode 150 are summed up corresponds to the height of the first insulating film 141.

In the trench gate type power semiconductor device, the insulating film for insulating the gate electrode and the emitter electrode is formed on the surface of the well layer, such that a step is generated on the surface of the emitter electrode formed on the well layer.

As described above, the step is generated on the surface of the emitter electrode, such that a contact area for wire bonding in a subsequent package assembling process is decreased, thereby making it possible to generate a problem that a wire is opened, or the like, which leads to a reliability problem of a product.

On the other hand, in the present embodiment, the interlayer dielectric 160 for insulating the first and second electrodes 150 and 170 is formed to be buried up to a predetermined depth in the trench 140, such that a surface of the well layer 130 may be planarized and a surface of the second electrode 170 formed on the planarized well layer 130 may also be planarized. Therefore, it is possible to solve the problems according to the prior art described above.

Further, in the present embodiment, the second electrode 170 is formed on the well layer 130. Here, the second electrode 170 may have a first surface contacting the surface of the well layer 130 and a second surface corresponding to the first surface.

Here, the first surface may have a portion 170b contacting the surface of the well layer 130 and a portion 170a inserted into the trench 140 to contact the interlayer dielectric 160.

That is, as described above, both of the first electrode 150 and the interlayer dielectric 160 are formed to be buried in the trench 140 and are formed up to the height at which the first insulating film 141 is formed. Here, the first insulating film 141 is formed from the bottom surface 140b of the trench 140 up to a predetermined height (the region b) in the thickness direction and is not formed from the inlet of the trench 140 up to a predetermined depth (the region a).

Therefore, a groove 131 concave from a surface in the thickness direction may be formed at a portion at which the trench 140 is formed in the well layer 130 before the second electrode 170 is formed, and the second electrode 170 formed on the well layer 130 may include a protrusion part 170a inserted into the concave groove 131 to contact the interlayer dielectric 160.

As described above, since the protrusion part 170a of the second electrode 170 is inserted into the region a of the trench 140 and the first insulating film 141 is not formed on an outer wall of the region a of the trench 140, a contact area between the second electrode 170 and the second electrode region 180 may be increased. Therefore, an interval of the trench 140 is implemented at a fine pitch without increasing contact resistance to increase channel density, thereby making it possible to decrease conduction loss.

In addition, the trench gate type power semiconductor device 100 according to the present embodiment may further include second electrode regions 180 formed in the well layer 130 so as to contact the first surface of the second electrode 170 and outer walls 140a of each of the trenches 140 and formed between the trenches 140 adjacent to each other so as to be spaced apart from each other.

Here, the second electrode regions 180 may be an N+ type having a concentration higher than that of the above-mentioned N type drift layer 120, but is not particularly limited thereto.

Therefore, the second electrode regions 180 may be formed by injecting N+ type impurities into positions adjacent to the trenches 140 in the surface of the well layer 130 and diffusing the N+ type impurities, but is not particularly limited thereto.

In addition, the trench gate type power semiconductor device 100 according to the present embodiment may further include body regions 190 formed between the second electrode regions 180 spaced apart from each other in the well layer 130 so as to contact each of the second electrode regions 180 and the first surface of the second electrode 170.

Here, the body region 190 may be a P+ type having a concentration higher than that of the P type well layer 130 in order to provide low contact resistance to the second electrode 170, but is not particularly limited thereto.

In addition, although not shown, the trench gate type power semiconductor device 100 according to the present embodiment may further include an N+ type layer formed between the N type drift layer 120 and the P type well layer 130 and having a concentration higher than that of the drift layer 120.

As described above, the N+ type layer having a high concentration is formed between the drift layer 120 and the well layer 130, thereby making it possible to prevent holes from penetrating from the semiconductor substrate 110 to the second electrode 170, which is the emitter electrode, and accumulate the holes to decrease turn-on voltage.

### Second Preferred Embodiment

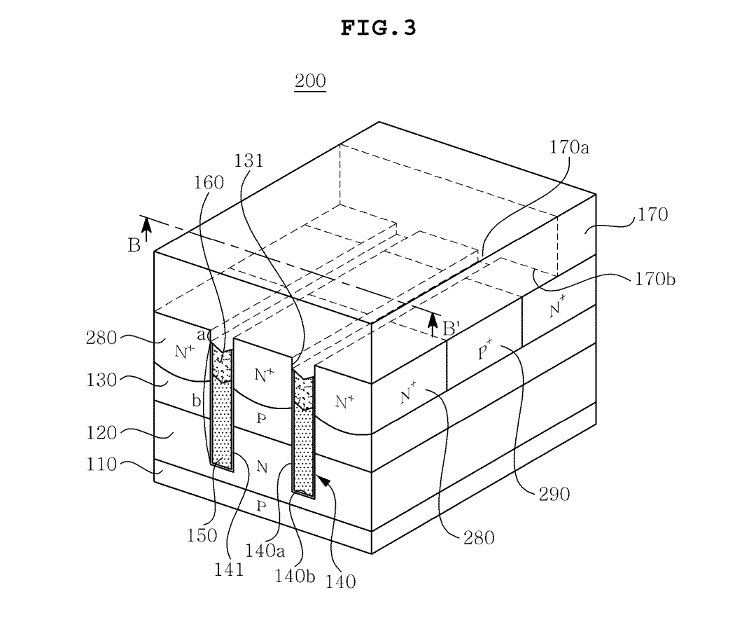

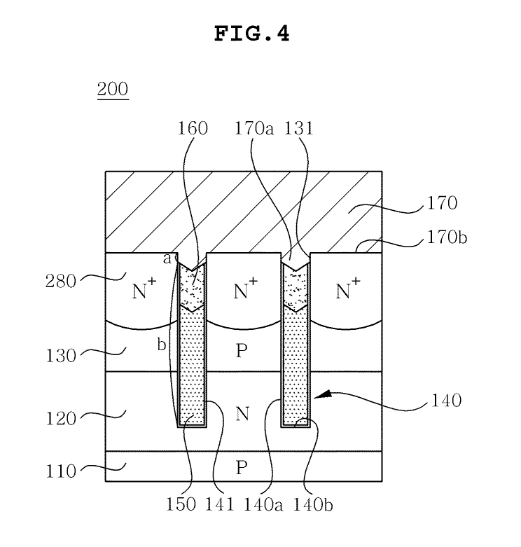

FIG. 3 is a perspective view showing a structure of a trench gate type power semiconductor device according to a second preferred embodiment of the present invention; and FIG. 4 is a cross-sectional view of the trench gate type power semiconductor device according to the second preferred embodiment of the present invention taken along the line B-B′ of FIG. 3.

In the present embodiment, a description of components overlapped with the components described in the above-mentioned first preferred embodiment will be omitted. In addition, the same reference numerals will be used to describe the same components as the components described in the first preferred embodiment.

The trench gate type power semiconductor device 200 according to the present embodiment is different from the trench gate type power semiconductor device 100 according to the first preferred embodiment of the present invention in that second electrode regions 280 and body regions 290 contacting the second electrode regions 280 may be alternately disposed in a length direction of the trench 140, as shown in FIG. 3.

More specifically, referring to FIG. 3, the second electrode regions 280 contact the trenches 140 in the length direction of the trench 140 and are formed to be spaced apart from each other by a predetermined interval, and the body regions 290 are formed between the second electrode regions 280 formed to be spaced apart from each other so as to contact the second electrode regions 280.

Here, a sequence in which the second electrode regions 280 and the body regions 290 are disposed is not particularly limited.

As an interval between the trenches 140 has been recently implemented at a fine pitch, it has been difficult to form both of the second body region 280 and the body region 290 between the trenches 140.

Therefore, as in the present embodiment, the second electrode regions 280 and the body regions 290 are formed to be alternately disposed in the length direction of the trench 140, such that they may be easily formed between the trenches 140 having the fine pitch, as compared with the pattern according to the first preferred embodiment of the present invention.

In addition, both of the second electrode region 280 and the body region 290 are formed to contact the outer wall of the trench 140, such that a contact area between the body region 290 and the second electrode 170 as well as a contact area between the second electrode region 280 and the second electrode 170 is increased, thereby making it possible to doubly increase a contact resistant decrease effect, as compared with the structure according to the first preferred embodiment of the present invention in which only the contact area between the second electrode 180 and the second electrode 170 is increased.

In addition, only one region is formed between the trenches 140, thereby making it possible to prevent misalignment that may be generated at the time of forming the second electrode region 280 and the body region 290, as compared with the structure according to the first preferred embodiment of the present invention.

According to the preferred embodiments of the present invention, the interlayer dielectric is buried in the trench to realize the planarization of the surface of the second electrode, thereby making it possible to solve a wire bonding defect that may be generated at the time of assembling a package.

In addition, according to the preferred embodiments of the present invention, the first insulating film is not formed from the inlet of the trench up to a predetermined depth and the second electrode is formed to be inserted into the portion at which the first insulating film is not formed, such that the contact area with the second electrode is increased, thereby making it possible to prevent an increase in contact resistance.

Further, according to the preferred embodiments of the present invention, the interlayer dielectric is formed to be buried in the trench, making it possible to solve a contact misalignment problem between the trench and the second electrode that may be generated at the time of forming the interlayer dielectric.

Furthermore, according to the preferred embodiments of the present invention, the contact misalignment problem between the trench and the second electrode is solved to prevent current from being biased in one direction, thereby making it possible to prevent a product destruction phenomenon due to passage of a large amount of current.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A trench gate type power semiconductor device comprising:
a first conductive type semiconductor substrate having one surface and the other surface;
a second conductive type drift layer formed on one surface of the semiconductor substrate;
a first conductive type well layer formed on the drift layer;
trenches formed from a surface of the well layer so as to arrive at the drift layer while penetrating through the well layer in a thickness direction;
first insulating films formed on inner walls of the trenches and formed from bottom surfaces of the trenches up to a predetermined height;
first electrodes formed at a height lower than that of the first insulating films in the trenches;
interlayer dielectrics formed on the first electrodes in the trenches and formed up to the same height as that of the first insulating films; and
a second electrode formed on the well layer and having a first surface contacting the surface of the well layer and a second surface facing the first surface, a portion of the first surface corresponding to the trenches being protruded into the trenches to contact the interlayer dielectrics.

2. The trench gate type power semiconductor device as set forth in claim 1, wherein the first conductive type is a P type and the conductive type is an N type.

3. The trench gate type power semiconductor device as set forth in claim 2, further comprising:
N type second electrode regions formed in the well layer so as to contact the first surface of the second electrode and outer walls of each of the trenches, formed between the trenches adjacent to each other so as to be spaced apart from each other, and having a concentration higher than that of the drift layer; and
P type body regions formed between the second electrode regions spaced apart from each other in the well layer so as to contact the second electrode regions and the first surface of the second electrode and having a concentration higher than that of the well layer,
wherein the number of trenches is plural.

4. The trench gate type power semiconductor device as set forth in claim 2, further comprising:
N type second electrode regions formed between the trenches adjacent to each other in the well layer so as to contact the first surface of the second electrode and outer walls of each of the trenches, formed to be spaced apart from each other in a length direction of the trench, and having a concentration higher than that of the drift layer; and
P type body regions formed between the second electrode regions spaced apart from each other so as to contact the second electrode regions and the first surface of the second electrode and having a concentration higher than that of the well layer,
wherein the number of trenches is plural.

5. The trench gate type power semiconductor device as set forth in claim 2, further comprising an N type buffer layer formed between the P type semiconductor substrate and the N type drift layer and having a concentration higher than that of the drift layer.

6. The trench gate type power semiconductor device as set forth in claim 2, further comprising an N type layer formed between the N type drift layer and the P type well layer and having a concentration higher than that of the drift layer.

7. The trench gate type power semiconductor device as set forth in claim 1, wherein the first electrode is made of poly silicon.

8. The trench gate type power semiconductor device as set forth in claim 1, wherein the first electrode is a gate electrode and the second electrode is an emitter electrode.

9. The trench gate type power semiconductor device as set forth in claim 1, wherein the interlayer dielectric is made of boron phosphorus silicate glass (BPSG).

10. The trench gate type power semiconductor device as set forth in claim 1, further comprising a third electrode formed on the other surface of the semiconductor substrate.

11. The trench gate type power semiconductor device as set forth in claim 10, wherein the third electrode is a collector electrode.

12. A trench gate type power semiconductor device comprising:
a first conductive type semiconductor substrate having one surface and the other surface;
a second conductive type drift layer formed on one surface of the semiconductor substrate;
a first conductive type well layer formed on the drift layer;
trenches formed from a surface of the well layer so as to arrive at the drift layer while penetrating through the well layer in a thickness direction;
first insulating films formed on inner walls of the trenches and formed from bottom surfaces of the trenches up to a predetermined height;
first electrodes formed at a height lower than that of the first insulating films in the trenches;
interlayer dielectrics formed on the first electrodes in the trenches and formed up to the same height as that of the first insulating films;
a second electrode formed on the well layer and having a first surface contacting the surface of the well layer and a second surface facing the first surface, a portion of the first surface corresponding to the trenches being protruded into the trenches to contact the interlayer dielectrics;
N type second electrode regions formed in the well layer so as to contact the first surface of the second electrode and outer walls of each of the trenches, formed between the trenches adjacent to each other so as to be spaced apart from each other, and having a concentration higher than that of the drift layer; and
P type body regions formed between the second electrode regions spaced apart from each other in the well layer so as to contact the second electrode regions and the first surface of the second electrode and having a concentration higher than that of the well layer,
wherein the first conductive type is a P type, the conductive type is an N type, and the number of trenches is plural.

13. A trench gate type power semiconductor device comprising:
a first conductive type semiconductor substrate having one surface and the other surface;
a second conductive type drift layer formed on one surface of the semiconductor substrate;
a first conductive type well layer formed on the drift layer;
trenches formed from a surface of the well layer so as to arrive at the drift layer while penetrating through the well layer in a thickness direction;
first insulating films formed on inner walls of the trenches and formed from bottom surfaces of the trenches up to a predetermined height;
first electrodes formed at a height lower than that of the first insulating films in the trenches;
interlayer dielectrics formed on the first electrodes in the trenches and formed up to the same height as that of the first insulating films;
a second electrode formed on the well layer and having a first surface contacting the surface of the well layer and a second surface facing the first surface, a portion of the first surface corresponding to the trenches being protruded into the trenches to contact the interlayer dielectrics;
N type second electrode regions formed between the trenches adjacent to each other in the well layer so as to contact the first surface of the second electrode and outer walls of each of the trenches, formed to be spaced apart from each other in a length direction of the trench, and having a concentration higher than that of the drift layer; and
P type body regions formed between the second electrode regions spaced apart from each other so as to contact the second electrode regions and the first surface of the second electrode and having a concentration higher than that of the well layer,
wherein the first conductive type is a P type, the conductive type is an N type, and the number of trenches is plural.
